(19) United States
(12) Patent Application Publication
(10) Pub. No.: US 2015/0362374 A1
(43) Pub. Date: Dec. 17, 2015

(54) Atomic Layer Deposition of Vanadium Oxide for Microbolometer and Imager

(71) Applicants: Virginia D. Wheeler, Alexandria, VA (US); Francis J. Kub, Arnold, MD (US); Charles R. Eddy, JR., Columbia, MD (US); Marko J. Tadjer, Springfield, VA (US)

(72) Inventors: Virginia D. Wheeler, Alexandria, VA (US); Francis J. Kub, Arnold, MD (US); Charles R. Eddy, JR., Columbia, MD (US); Marko J. Tadjer, Springfield, VA (US)

(73) Assignee: The Government of the United States of America, as represented by the Secretary of the Navy, Washington, DC (US)

(21) Appl. No.: 14/729,441

(22) Filed: Jun. 3, 2015

Related U.S. Application Data
(60) Provisional application No. 62/012,600, filed on Jun. 16, 2014.

(51) Int. Cl. G01J 5/20; H01L 37/00

(52) U.S. Cl. CPC G01J 5/20; H01L 37/00; G01J 2005/202; G01J 2005/0077

(57) ABSTRACT

This disclosure describes a microbolometer sensor element and microbolometer array imaging devices optimized for infrared radiation detection that are enabled using atomic layer deposition (ALD) of vanadium oxide material layer (VOₓ) for a temperature sensitive resistor.

### REFERENCE TO RELATED APPLICATION

This application claims priority to and the benefits of U.S. Patent Application No. 62/012,600 filed on Jun. 16, 2014, the entirety of which is herein incorporated by reference.

### BACKGROUND

An infrared focal plane array typically consists of an array of infrared sensing pixels and a silicon CMOS multiplexing and readout circuitry. The infrared sensing pixel typically has a microbolometer sensor element and a pixel selection transistor. The infrared focal plane array can be a monolithic focal plane array or a hybrid focal plane array. The design for the pixels in monolithic infrared focal plane array often has the microbolometer sensor element formed above and electrically connected to the pixel selection transistor form in a silicon substrate with CMOS multiplexing and readout circuitry formed in the silicon substrate at the edge of the microbolometer array.

The microbolometer sensor element typically uses a temperature sensitive resistor as a transducer to indicated the amount of infrared radiation that is absorbed in each pixel. Unsaturated vanadium oxide (VOₓ) is often used as a temperature sensitive resistor. The unsaturated vanadium oxide is typically deposited using sputtering deposition approaches.

Thermal isolation of a microbolometer sensor element is essential to achieving high infrared focal plane array sensor performance. Thermal isolation is typically achieved by implementing a temperature sensitive resistor on a floating membrane using support structures which have high thermal resistance. The floating membranes are typically fabricated by depositing a membrane material layer onto a sacrificial layer which is later removed to implement a self-supporting floating membrane.

Infrared focal plane array imager consisting of microbolometer sensing elements can be packaged in a vacuum to reduce the thermal conductance to the surrounding material layers.

One of the primary applications for infrared focal plane arrays consisting of an array of microbolometer sensor elements is for uncooled infrared focal plane array imagers. Uncooled infrared focal plane array are attractive for because cryogenic cooling infrastructure is not required for operation.

### BRIEF SUMMARY OF THE INVENTION

A microbolometer sensor element and microbolometer infrared focal plane array imaging devices optimized for infrared radiation detection that are enabled using atomic layer deposition of unsaturated vanadium oxide (VOₓ) film that is used for a temperature sensitive resistor within the microbolometer. A primary application area for this microbolometer sensor and microbolometer infrared focal plane array imaging device is for uncooled infrared imaging, however, other applications include infrared sensing with the imager cooled to cryogenic temperatures and also infrared sensing with above room temperature operation temperatures.

The microbolometer infrared focal plane array imaging device can include a planar infrared imager, a curved infrared imager, a tunable curved infrared imager, a dynamically tunable curved infrared imager, a hemispherical curved infrared imager, an infrared imager on a flexible substrate, a partially stretchable or entirely stretchable infrared imager. The microbolometer sensor element can include a planar microbolometer sensor element, a three-dimensional microbolometer sensor element that achieves low resistance value for a thermal sensitive resistor formed using thin VOₓ material layer, or a three-dimensional microbolometer sensor element that implements a self-absorbing internal optical cavity microbolometer.

### BRIEF DESCRIPTION OF THE DRAWINGS

FIG. 1 illustrates a cross section of atomic layer deposited vanadium oxide film on a floating membrane used for a temperature sensitive resistor for a microbolometer sensor element.

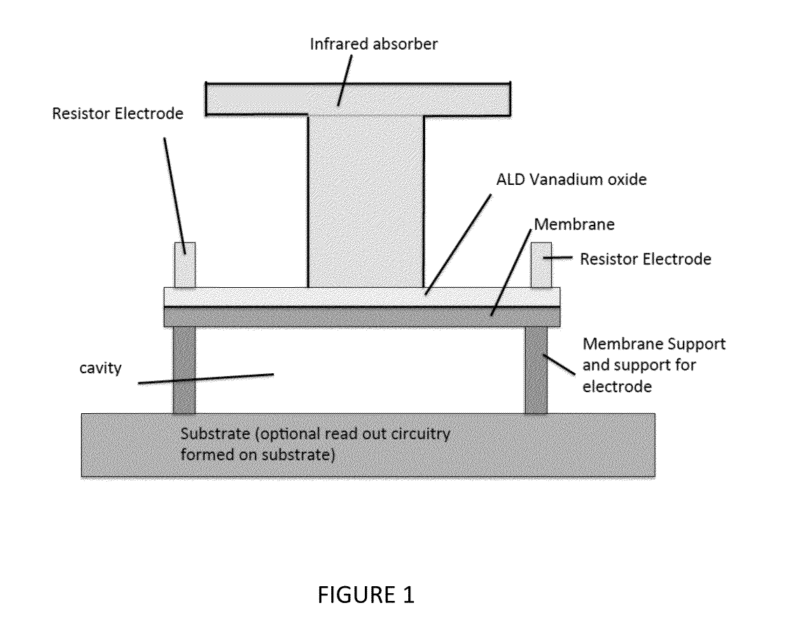

FIG. 2 illustrates a cross section of large effective thickness vanadium oxide infrared absorber or terahertz absorber on membrane for microbolometer sensor.

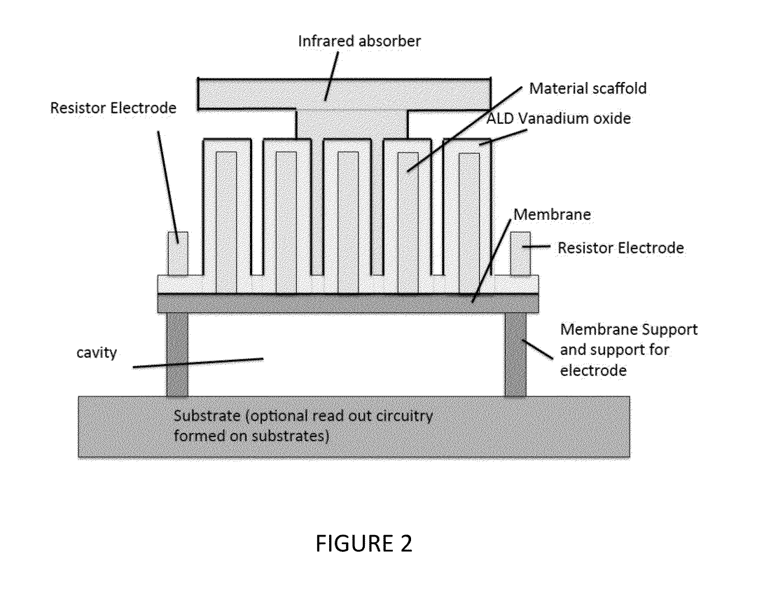

FIG. 3 illustrates a self-absorbing internal optical cavity microbolometer, semiconductor film microbolometer. The thickness of the semiconductor heat sensitive layer must now be equal to λ/4n, where λ is the wavelength of maximum absorption and n is the effect refractive index of the thermal coefficient of resistance (TCR) resistive layer.

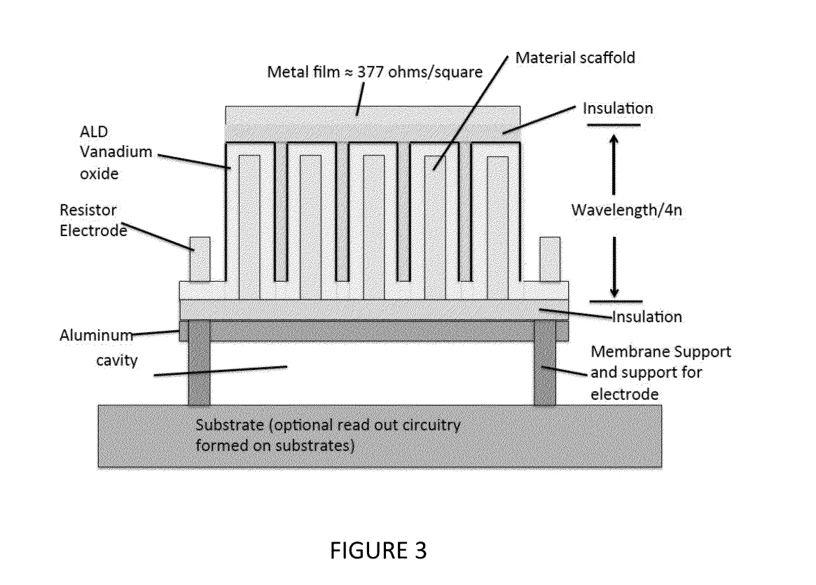

FIG. 4 illustrates the top view of large effective thickness vanadium oxide infrared absorber or terahertz absorber on membrane for microbolometer sensor.

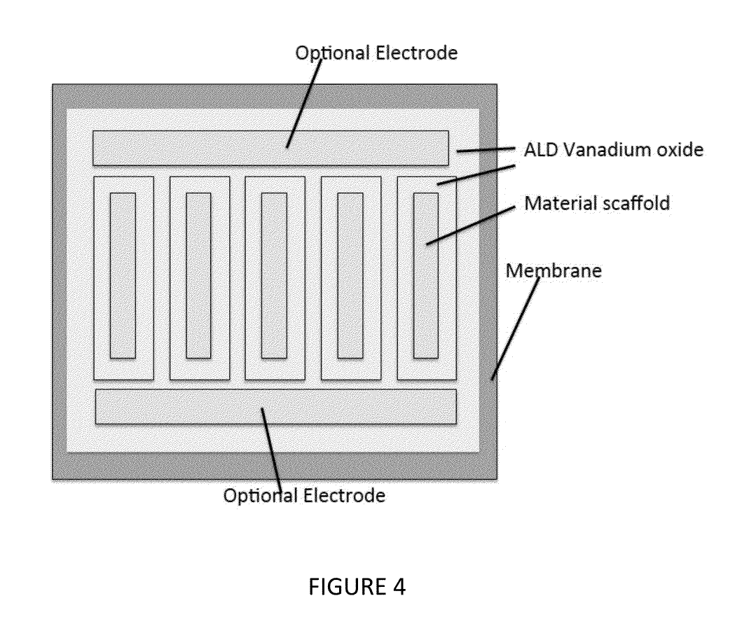

FIG. 5 illustrates the top view of large effective thickness vanadium oxide infrared absorber or terahertz absorber on membrane for microbolometer sensor. Electrode overlaps the ALD vanadium oxide material deposited on the 3D material scaffold for lower resistance.

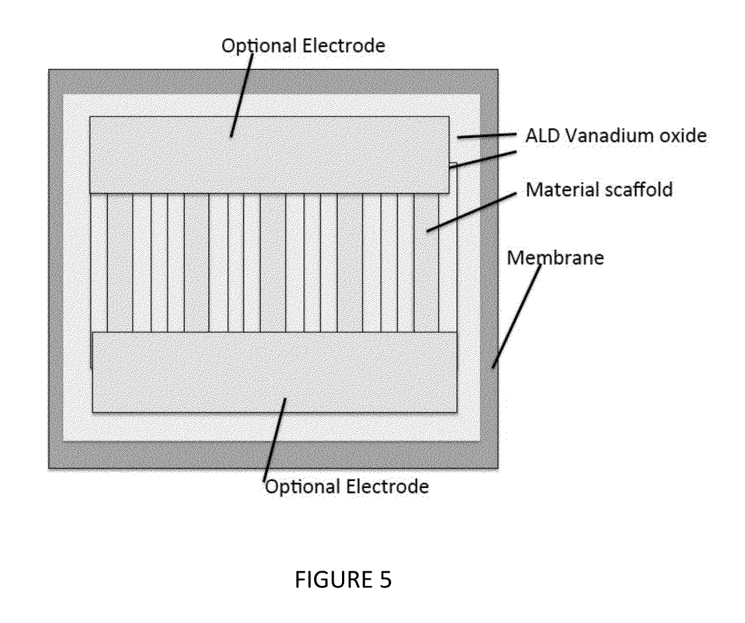

FIG. 6 illustrates XPS spectra taken after different ion sputtering times. The top surface of the film corresponds to 0s. The initial surface shows components of both V₂O₅ and VO₂ while nearer the substrate interface (28s) shows the presence of an oxygen deficient component.

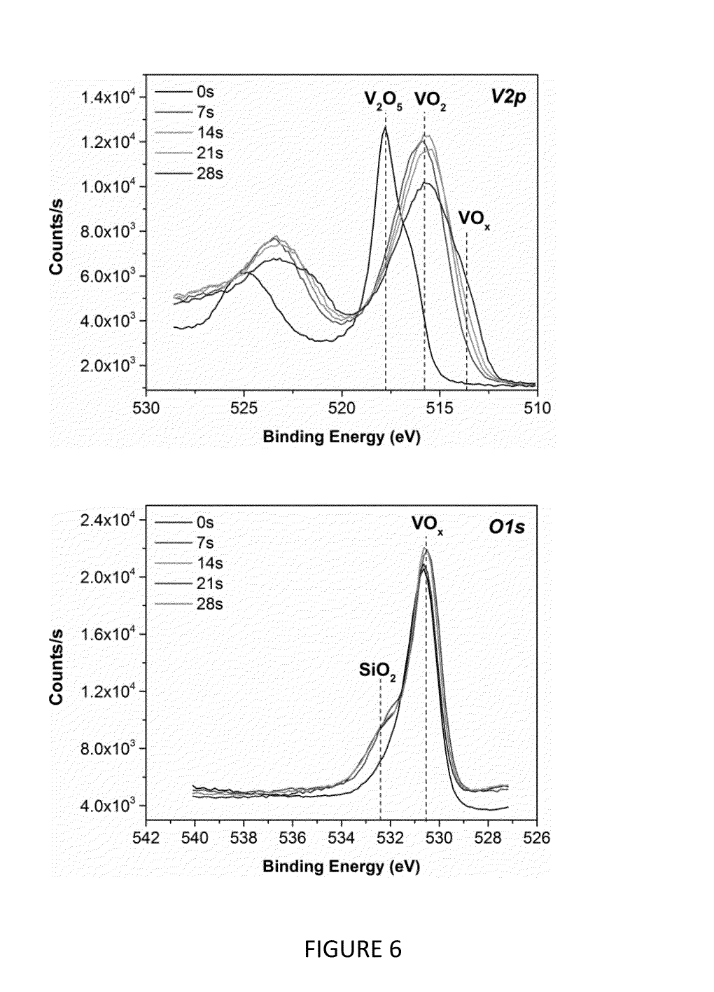

FIG. 7 illustrates electrical properties as a function of temperature of 7, 15, and 34 nm thick films grown on substrates of Si (open symbols) and sapphire (filled symbols). The amorphous films exhibit a nine order of magnitude change in resistance over the 77-500K temperature range.

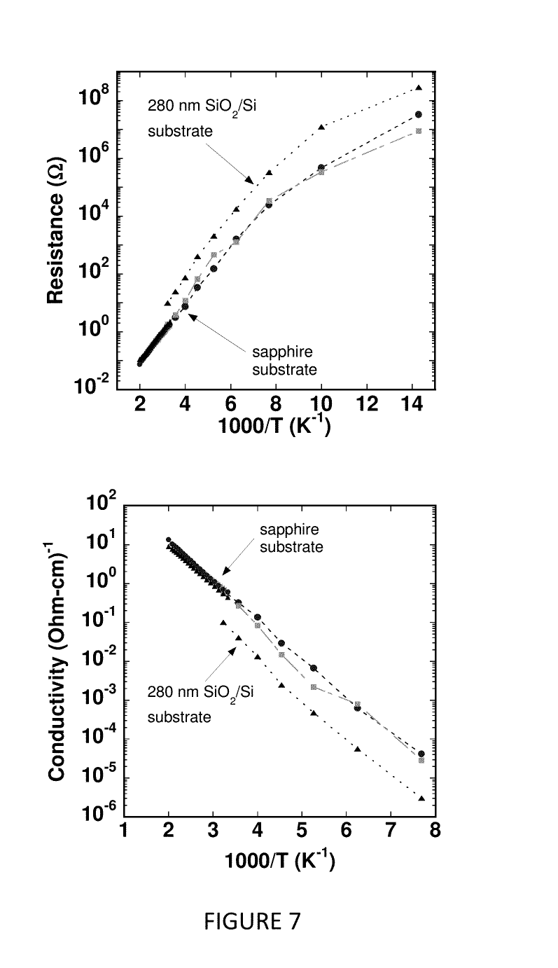

FIG. 8 illustrates a cross section of bolometer pixel array having one or more bolometer sensors elements (pixels) and one or more than one silicon CMOS die(s) on a flexible substrate with microelectronic formed metal interconnects across the insulated etch of a silicon die used to connect the silicon CMOS readout integrated circuit (ROIC) to the bolometer pixel array. The flexible substrate can be curved and stretched to implement a hemispherical, cylindrical, curvilinear curved infrared focal plane imager. The curved surface can be convex or concave.

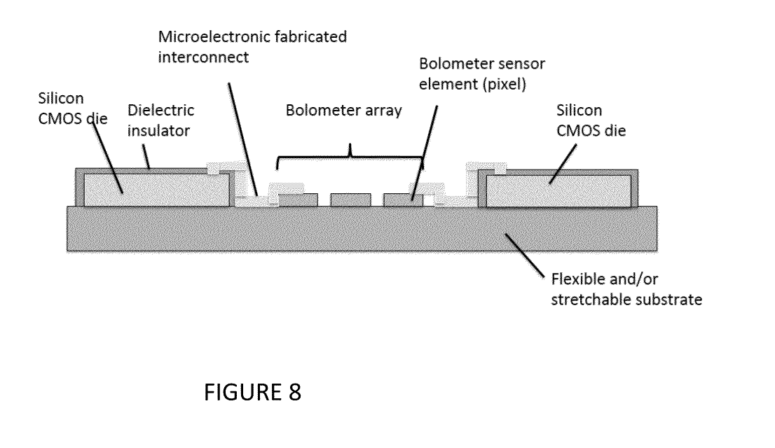

FIG. 9 illustrates a cross section of bolometer pixel array having one or more bolometer sensors elements (pixels) and one or more than one silicon CMOS die(s) on a flexible substrate with microelectronic formed metal interconnects and a through polymer via used to connect the silicon CMOS readout integrated circuit (ROIC) to the bolometer pixel array. The flexible substrate can be curved and stretched to implement a hemispherical, cylindrical, curvilinear curved infrared focal plane imager. The curved surface can be convex or concave.

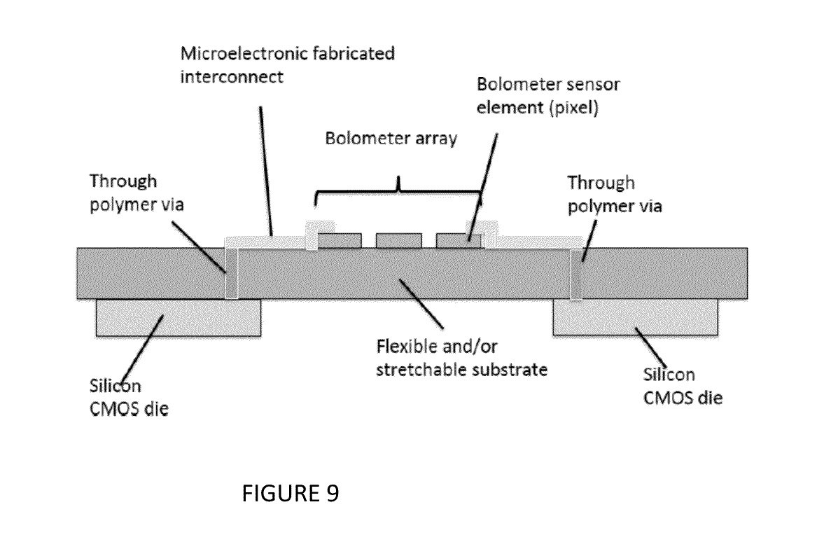

FIG. 10 illustrates the cross section of a pixel element having both a bolometer sensor element and a thin film transistor (TFT) pixel selection transistor formed on a flexible substrate. The bolometer sensor element can be formed above the TFT pixel selection transistors or alternately, the bolometer sensor element can be formed laterally separated (to one side) from the bolometer sensor element. Because the polymer has low thermal conductivity, the temperature sensitive resistor can be formed on the flexible substrate material (without a cavity beneath the thermal sensitive resistor). A bolometer sensor with a cavity will have higher thermal response while the bolometer sensor element with temperature sensitive resistor formed on the flexible substrate will have lower manufacturing cost.

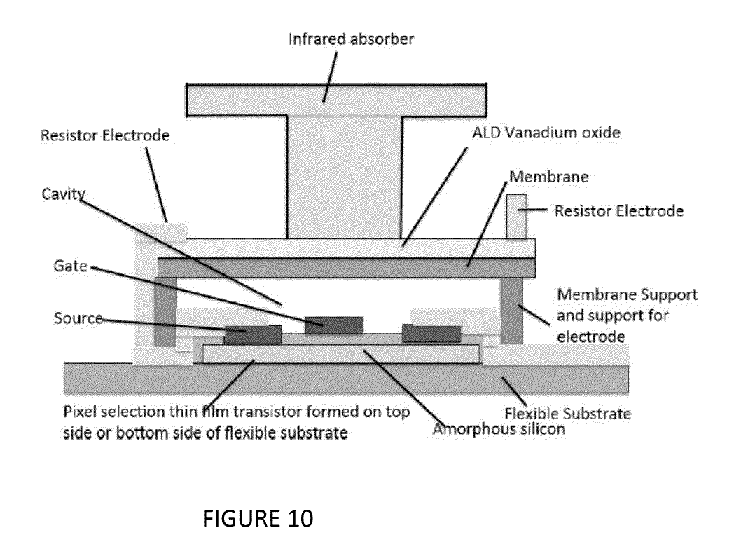

FIG. 11 illustrates a cross section of bolometer pixel array having one or more bolometer sensors elements (pixels) and one or more than one silicon CMOS die(s) on a flexible substrate. The flexible substrate can be curved and stretched to implement a hemispherical, cylindrical, curvilinear curved infrared focal plane imager with optional curved and flat support surface. The curved surface can be convex or concave.

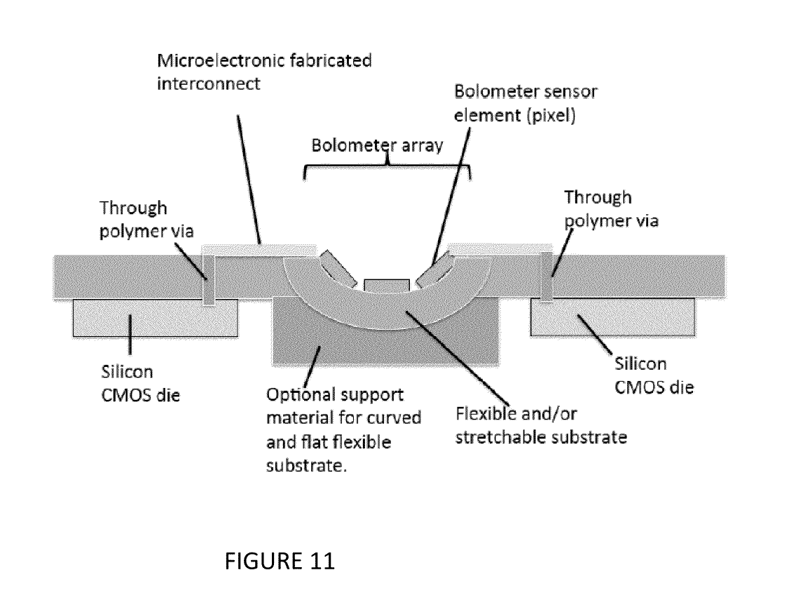

FIG. 12 illustrates a cross section of bolometer pixel array having one or more bolometer sensors elements (pixels) and one or more than one silicon CMOS die(s) on a flexible substrate. The flexible substrate can be curved and stretched to implement a hemispherical, cylindrical, curvilinear curved infrared focal plane imager with optional curved and flat support surface. Actuators (for example linear actuators) can be used to dynamically tune the curvature of the infrared focal plane array on a flexible substrate. The curved surface can be convex or concave.

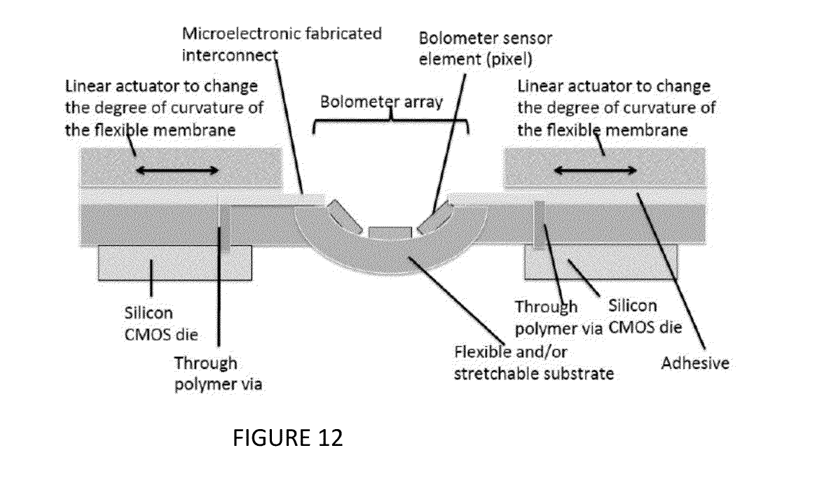

FIG. 13 illustrates a cross section of bolometer pixel array having one or more bolometer sensors elements (pixels) and one or more than one silicon CMOS die(s) on a flexible substrate. The flexible substrate can be curved and stretched to implement a hemispherical, cylindrical, curvilinear curved infrared focal plane imager with optional curved and flat support surface. Pressure from a fluid either on the backside or front side of a cavity formed adjacent to the flexible substrate/bolometer pixel array of the can be used to dynamically tune the curvature of the infrared focal plane array on a flexible substrate. The curved surface can be convex or concave.

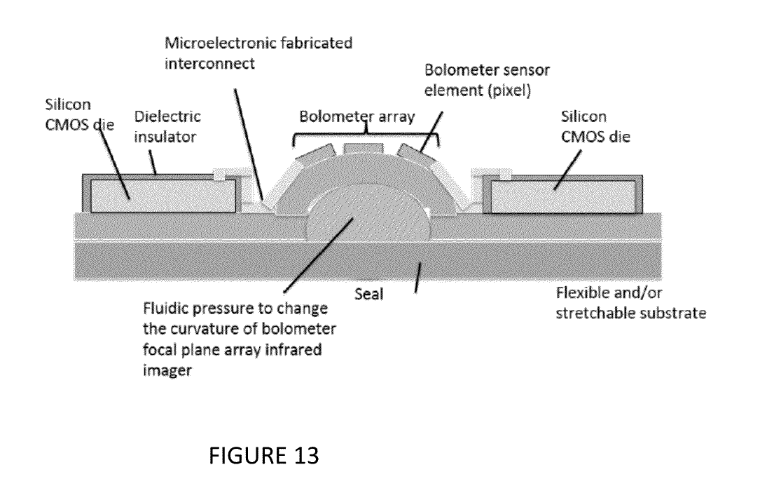

### DETAILED DESCRIPTION

Aspects of this disclosure include a microbolometer sensor element and microbolometer infrared focal plane array imaging devices optimized for infrared radiation detection that are enabled using atomic layer deposition of unsaturated vanadium oxide (VOₓ) film that is used for a temperature sensitive resistor within the microbolometer. A primary application area for this microbolometer sensor and microbolometer infrared focal plane array imaging device is for uncooled infrared imaging, however, other applications include infrared sensing with the imager cooled to cryogenic temperatures and also infrared sensing with above room temperature operation temperatures. The microbolometer infrared focal plane array imaging device can include a planar infrared imager, a curved infrared imager, a tunable curved infrared imager, a dynamically tunable curved infrared imager, a hemispherical curved infrared imager, an infrared imager on a flexible substrate, a partially stretchable or entirely stretchable infrared imager. The microbolometer sensor element can include a planar microbolometer sensor element, a three-dimensional microbolometer sensor element that achieves low resistance value for a thermal sensitive resistor formed using thin VOₓ material layer, or a three-dimensional microbolometer sensor element that implements a self-absorbing internal optical cavity microbolometer.

The unsaturated ALD vanadium oxide film may be a mixed oxide film with multiple phases of vanadium oxide molecules. For example, the unsaturated ALD vanadium oxide material may have both VO₂ and V₂O₅ molecules. The ALD vanadium oxide film may comprise entirely amorphous vanadium oxide material or partially amorphous vanadium oxide material. The ALD vanadium oxide film may comprise amorphous material with a high VO₂ molecule content. For example, the ALD vanadium oxide film may comprise a film with greater than 90 percent VO₂ molecules. A vanadium oxide amorphous film with a high VO₂ content may have a gradual change in resistance value of the temperature sensitive resistor of a microbolometer with operation temperature. For certain fabrication process using selected precursor material such as tetrakis(ethylmethyl)amido vanadium precursor with ozone reactant, a vanadium oxide film deposited by atomic layer deposition at 150° C. is an amorphous material film with greater than 90 percent VO₂ molecular content and has a gradual change in resistance values with operating temperature with a TC.R of about 2.3% per degree K at 300° K and a conductivity of about 0.6/(ohm-cm) without any further anneal. Thus, the ALD deposited vanadium oxide film can thus have a high TCR for an unannealed vanadium oxide film. The tetrakis(ethylmethyl)amido vanadium precursor with ozone reactant precursor used for the vanadium oxide deposition can be used to deposit film at a temperature as low as 115° C.

The ALD vanadium oxide material may be annealed to partially or entirely crystallize the vanadium oxide layer to optimize the resistance value of the temperature sensitive resistor of a microbolometer. The ALD vanadium oxide material may be laser annealed to partially or entirely crystalize the vanadium oxide layer to optimize the resistance value of the temperature sensitive resistor of a microbolometer that is formed on a polymer substrate.

ALD deposition of VOₓ films to implement thermally sensitive resistor for microbolometer sensor elements for infrared focal plane array imager or terahertz focal plane array imager allows for several advantages. Advantages of the ALD VOₓ film for the temperature sensitive resistor include deposition at a temperature as low as 115° C., high TCR for unannealed VOₓ film, deposition temperature that compatible with flexible polymer substrates, deposition temperature that is compatible with low coefficient of thermal expansion flexible polymer substrates, enabling deposition on a polymer surface, excellent uniformity less than 2 percent over the wafer surface, and ability for a conformal deposition on three-dimensional surfaces.

Atomic layer deposition can be used to deposit unsaturated vanadium oxide VOₓ material that has a temperature coefficient of resistivity of approximately 2.3 percent per degree centigrade at room temperature.

The ALD VOₓ film permits a microbolometer infrared focal plane array operation in the temperature range of about 77K to about 500K.

ALD is a repeatable, highly uniform, conformal, pinhole free, manufacturable process for depositing ultrathin film layers that is compatible with modern VLSI fabrication. Advantages of the ALD VOₓ film include excellent uniformity of the thickness of the film, uniformity of resistance of the film, uniformity of noise property of the film over the surface of an entire wafer that will enable excellent microbolometer sensor element uniformity within an array and excellent uniformity of microbolometer infrared focal plane array imagers over an entire wafer. The low distribution of TCR values will increase pixel yield and reduce the amount of nonuniformity correction in the read out electronics. Excellent array uniformity means that the array gain can be increased prior to digitization in order to improve overall system signal-to-noise performance.

Fast thermal response is important to enable high frame rate for bolometer infrared focal plane array imagers. Low thermal mass is necessary to achieve fast thermal response. The low thickness for ALD VOₓ enables low thermal mass that enables fast microbolometer sensor element response. In addition, low thickness of ALD enables low stress films.

The ALD vanadium oxide film can be deposited at low temperatures. The ALD films deposited at 150° C. The ALD vanadium oxide film can be deposited at as low as 115° C. Low ALD VOₓ deposition temperature enables deposition on sacrificial polymer films that can be undercut for easy formation of the floating membrane. Low deposition temperature ALD VOₓ film enables fabrication of microbolometer sensor elements on a flexible substrate. The flexible substrate can include but not be limited to be a polymer, a flexible glass and thinned silicon. The flexible substrate can be advantageous for a microbolometer infrared focal plane array curved imager for improved imager performance a microbolometer infrared focal plane array that conforms to a curved surface, or a microbolometer infrared focal plane array imager that flexes without degradation. Advances of a curved infrared focal plane imager include reduced number of lenses needed to reduce optical aberrations and increases the field of view (FOV) of the imager. The microbolometer infrared focal plane array on flexible substrate can be advantageous for wearable electronics.

Low deposition temperature ALD VOₓ film has advantage of being able to be deposited on flexible polymer substrates that advantageous because of low coefficient of thermal expansion that is important for integrating silicon material and circuits and vanadium oxide material on the flexible substrate. Two polymer materials that are advantageous for flexible substrates because of low linear coefficient of thermal expansion, low moisture absorption, large Young's modulus, large tensile strength are Polyethylene terephthalate (PET) and polyethylene naphthalate (PEN), however, PET and PEN have relatively low glass transition temperature and maximum process temperature. PET has a glass transition temperature of about 78° C. and PEN has a glass transition temperature of about 121° C. PET has a maximum process temperature of about 150° C. and PEN has a maximum process temperature of about 200° C. It is advantageous for the deposition process for depositing vanadium oxide material has a process temperature less than 150° C. for PET and a process temperature less than about 200° C. for PEN substrates. The low ALD deposition temperature for depositing vanadium oxide materials is advantageous for the use of PET and PEN flexible substrates. For example, Polyethylene terephthalate (PET) has a linear thermal expansion coefficient of about 15 ppm/° C. and polyethylene naphthalate (PEN) has a linear coefficient of thermal expansion of about 13 ppm/° C. at 300K. Low ALD deposition temperature enables microbolometer sensor elements on a flexible polymer material substrate with linear coefficient of expansion less than 25. 1737 glass has a linear coefficient of thermal expansion of about 5 ppm/° C. PET and PEN absorb little water. The moisture absorption percentage for PET and PEN is about 0.14%. PET has a Young's modulus of about 5.3 GPa and PEN has a Young's Modulus of about 6.1 GPa. PET has a tensile strength of about 225 MPa and PEN has a Young's' Modulus of 275 MPa.

A comparison of the properties of PET and PEN compared to other plastic substrates for flexible substrate applications is given in Table 4.1 on page 78 of Flexible Electronics: Materials and Applications (2009) Springer edited by William S. Wong and Alberto Salleo.

| | PET | PEN | PC | PES | PI |
|---|---|---|---|---|---|
| | (Melinex) | (Teonex) | (Lexan) | (Sumilite) | (Kapton) |
| T_{g}, ° C. | 78 | 121 | 150 | 223 | 410 |
| CTE (−55 to | 15 | 13 | 60-70 | 54 | 30-60 |
| 85° C.), | | | | | |
| ppm/° C. | | | | | |
| Transmission | 89 | 87 | 90 | 90 | Yellow |
| (400-700 | | | | | |
| nm), % | | | | | |
| Moisture | 0.14 | 0.14 | 0.4 | 1.4 | 1.8 |
| abosrption, % | | | | | |
| Young's | 5.3 | 6.1 | 1.7 | 2.2 | 2.5 |
| modulus, Gpa | | | | | |
| Tensile | 225 | 275 | — | 83 | 231 |
| strength, Mpa | | | | | |
| Density, gcm⁻³ | 1.4 | 1.36 | 1.2 | 1.37 | 1.43 |
| Refractive | 1.66 | 1.5-1.75 | 1.58 | 1.66 | — |
| index | | | | | |
| Birefringence, | 46 | — | 14 | 13 | — |
| nm | | | | | |

The microbolometer array and readout electronics on flexible substrate assembly can be configured into a hemispherical curved focal plane array imager using techniques of conforming the microbolometer array and readout electronics on flexible substrate assembly to a hemispherical curved object and then adding supporting material on the backside of the assembly to fix the microbolometer array and readout electronics assembly into a hemispherical shape. It can be advantageous for the flexible substrate and the microbolometer array on flexible substrate to be stretchable. For example, when conforming microbolometer focal plane array to a hemispherical curved object, it is desirable for the polymer material and the microbolometer array on the polymer substrate to be stretchable to avoid folds in the polymer substrate. In an additional embodiment, mechanical or fluidic actuators can be connected to the backside of the microbolometer array and readout electronic integrated assembly to implement a dynamically tunable hemispherical curved focal plane array imager. Alternately, mechanical or fluidic actuators can be connected to the backside of the microbolometer array and readout electronics to implement a programmable tunable hemispherical curved focal plane array imager.

The ALD vanadium oxide film can be deposited on three-dimensional surfaces or on a three-dimensional scaffold. One advantage of the ability of ALD vanadium oxide films to deposit conformally on three-dimensional surfaces or scaffold is that the ALD vanadium oxide deposition technology enables a larger effective thickness of the vanadium oxide material and increasing the effective vanadium oxide thickness for infrared or terahertz electromagnetic absorption within the vanadium oxide material to enable a self-absorber, internal optical cavity A second advantage for the ability of ALD vanadium oxide films to be deposited on three-dimensional surfaces or scaffolds is that the cross sectional area for the temperature sensitive resistor can be increases which enables lower detector resistance, Rd, which enables lower Johnson noise.

### EXAMPLE 1

In some embodiments, an ALD vanadium oxide material layer may be deposited on a membrane material layer (from which a floating membrane will be formed) and be formed into temperature sensitive resistor for microbolometer sensor element for sensing an infrared electromagnetic radiation or a terahertz electromagnetic radiation. The materials that may be used for the floating membrane material layer may include a silicon nitride layer, a sputtered silicon nitride layer, or other dielectric or insulating layer. The ALD vanadium oxide or ALD doped vanadium oxide layer is fabricated into a temperature sensitive resistor.

In some embodiments, the ALD vanadium oxide or doped vanadium oxide material layer can have a thickness in the range of about lnm to 10nm. In some embodiments, the ALD vanadium oxide material layer can have a thickness in the range of about lnm to 20 nm. In some embodiments, the ALD vanadium oxide material layer can have a thickness in the range of about lnm to 50 nm. The ALD vanadium oxide material layer can have a thickness in the range of about lnm to 100 nm.

The thermal mass of the microbolometer sensor element can be reduced by reducing the thickness of vanadium oxide layer. The advantage of a low thickness for ALD vanadium oxide film is that the response time (thermal time constant) of the detector is related to the thermal mass of the temperature sensor and a low thermal mass is advantageous for fast detector response speed and high infrared focal plane array frame rates..

In some embodiments, the vanadium oxide material may be deposited at a temperature of about 115° C. In some embodiments, the ALD vanadium oxide material layer may be deposited at a temperature of about 150° C. In some embodiments, the ALD vanadium oxide material layer may be deposited at a temperature of about 200° C. In some embodiments, the ALD vanadium oxide material layer may be deposited at a temperature of about 300° C. In some embodiments, the ALD vanadium oxide material layer may be deposited at a temperature of about 400° C.

In some embodiments, the membrane material layer can be deposited on a sacrificial polymer with a glass transition temperature of about 100° C. The membrane material layer may be deposited on a sacrificial polymer with a glass transition temperature of about 150° C. The membrane material layer may be deposited on a sacrificial polymer with a glass transition temperature of about 200° C. The membrane material layer may be deposited on a sacrificial polymer with a transition temperature of about 300° C. An advantage of a sacrificial polymer layer with low glass transition temperature is to facilitate the removal of the sacrificial polymer layer to form a free standing floating membrane to reduce thermal conductance of the membrane to surrounding material layers.

A capping layer can be deposited on the surface of the VOₓ layer to improve the stability of the VOₓ layer. The capping layer maybe deposited by atomic layer deposition. The capping layer may be deposited within the same ALD system that is used to deposit the VOₓ layer. The capping layer material may include but not be limited to Al₂O₃ or HfO₂. An infrared absorber material layer may be deposited on the surface of the vanadium oxide layer and optionally patterned. In some embodiments, the infrared absorber material can be an undercut shape (mushroom shape) connected to the thermally sensitive resistor.

A cavity to enhance the infrared absorption can be formed using reflector material layers above and below the vanadium oxide layer. The cavity may be a quarter wavelength cavity. The cavity may be a resonant cavity. An infrared absorption material may be in contact with the vanadium oxide temperature sensitive resistor.

### EXAMPLE 2

### Large Effective Thickness ALD Vanadium Oxide Layer for Reduce Resistance

In some embodiments, it can be desirable to have a reduced resistance value for the temperature sensitive resistor to reduce the Johnson noise. An approach to increase the effective thickness and cross sectional area that is in contact with the resistor electrode contact is to deposit the ALD vanadium oxide on a three-dimensional scaffold or three-dimensional structured material. The effective resistance value of the vanadium oxide temperature sensitive resistor is inversely proportional to the cross sectional area. Thus, even though thin ALD vanadium oxide layers are deposited, the effective thickness and cross sectional area is large and the effective resistance value can be reduced. The electrode that contact the vanadium oxide may overlaps the vanadium oxide material deposited on the 3D material scaffold for lower resistance.

A cavity to enhance the infrared absorption can be formed using reflector material layers above and below the vanadium oxide layer. The cavity may be a quarter wavelength cavity. The cavity may be a resonant cavity.

A capping layer may be deposited on the surface of the VOₓ layer to improve the stability of the VOₓ layer. The capping layer maybe deposited by atomic layer deposition. The capping layer maybe deposited within the same ALD system that is used to deposit the VOₓ layer. The capping layer material may include but be limited to Al₂O₃ or HfO₂. An infrared absorber material layer may be deposited on the surface of the vanadium oxide layer. A cavity to enhance the infrared absorption may be formed using reflector material layers above and below the vanadium oxide layer

### EXAMPLE 3

### Self-Absorbing Microbolometer Sensor Element

In some embodiments, a large effective thickness vanadium oxide infrared absorber can be implemented by utilizing vanadium oxide deposited on a three-dimensional scaffold or three-dimensional structured material. The three-dimensional vanadium oxide film is formed in a cavity for infrared or terahertz absorption. The cavity may be formed into a self-absorbing internal optical cavity microbolometer. The effective thickness of the vanadium oxide infrared absorbing layer should be approximately equal to λ/4n, where λ is the wavelength of maximum absorption and n is the effect refractive index of the vanadium oxide infrared absorbing thermal sensitive resistive layer.

### EXAMPLE 4

### Flexible Microbolometer Infrared Focal Plane Array Imager and Curved Microbolometer Focal Plane Array Imager

In some embodiments, the substrate may comprise a flexible substrate material to implement an infrared focal plane array imager or terahertz focal plane array imager on a flexible substrate. The flexible substrate may include a glass substrate, a polymer substrate, or a composite substrate. In some embodiments, it is advantageous that the flexible substrate has a low value of linear coefficient of thermal expansion. The linear coefficient of thermal expansion of silicon is about 2.6 ppm/° C. Silicon CMOS circuits will typically be used for the readout electronics to sense and transform the signals from the microbolometer sensors (pixels) within a microbolometer focal plane array. It can be advantageous to implement a microbolometer focal plane array and readout electronics integrated circuit or assembly using flexible substrate with low linear coefficient of thermal coefficient of expansion so that there is less distortion and flexing of the microbolometer sensor elements and metal interconnects to the silicon readout electronics for improved reliability and reduced distortion. In some embodiments, it is advantageous for the flexible substrate to have a linear coefficient of thermal expansion that is less then about 17 ppm/° C. at 300° K. In some embodiments, it is advantageous for the flexible substrate to have a linear coefficient of thermal expansion this is less than about 25 ppm/° C. In some embodiments, it is desirable for the flexible substrate to be stretchable. In some embodiments, it is desirable for the flexible substrate to have low water absorption

A microbolometer focal plane array integrated circuit or integrated assembly will typically have a two-dimensional array of microbolometer sensor elements (pixels) (with selection transistor within each pixel) that are interconnected to one or more than one silicon CMOS multiplexing and readout circuits that are arranged on one or more then one sides of the two-dimensional array of microbolometer sensors. The selection transistor can comprise a Thin Film Transistor (TFT) that can be formed on a flexible substrate using techniques known to those of ordinary skill in the art. For example, the TFT can comprise amorphous silicon material, laser annealed amorphous material, graphene, carbon nanotubes, and other materials for forming TFT known to those skilled in the art. The electrical interconnect between the microbolometer two-dimensional array and the silicon CMOS multiplexing and readout circuit(s) can be microelectronic fabricated metal electrical interconnects or they can be wire bond or tape bond interconnects. The microelectronic fabricated metal electrical interconnects interconnection will typically be formed using flip chip bond, interconnect over the insulated edge of a silicon die, utilizing through-polymer-vias or through-glass-vias to connect to silicon CMOS die adhered to the flexible substrate on the bottom side of the flexible substrate. Microelectronic fabricated metal electrical interconnect typically uses metal deposition and photolithography resist patterning, and metal etching or metal liftoff to form the metal interconnects.

An embodiment for a flexible or curved infrared focal plane array integrated circuit or integrated assembly is to have the both the one or more silicon CMOS circuit die(s) and array of microbolometer sensor elements (pixels) integrated on a flexible substrate with the silicon CMOS circuit die(s) arranged on one or more of the lateral sides of the array of microbolometer sensors with microelectronic fabricated metal electrical interconnects over the sides of the silicon CMOS die(s), flip chip bond, wire bond, tape bond interconnects between the silicon CMOS circuit die(s) and the array of microbolometer sensors. In the case of the microelectronic fabricated metal electrical interconnect across the edge of the silicon CMOS dies(s) being used for the electrical connection between the silicon CMOS die(s) and the microbolometer sensor array, it can be advantageous to thin the silicon CMOS circuit die to about 20 micron thickness to facilitate the formation of microelectronic fabricated metal electrical interconnects over the edge of the silicon CMOS die. Alternately, the silicon CMOS die(s) can be flip chip mounted to microelectronic fabricated metal electrical interconnects formed on the flexible substrate using bump bond approaches. Alternately, the can be wire bonds or tape bond between the silicon CMOS die(s) and the microbolometer array. This embodiment for the having silicon CMOS die(s) on the lateral sides of the microbolometer sensor array permits the flexible substrate and microbolometer array to be stretched to conform to curved shapes such as hemispherical, cylindrical, curvilinear, or other curved shape to form a hemispherical, cylindrical, curvilinear or other curved infrared imager.

In some embodiments, since polymers typically have a low thermal conductivity value, the thermally sensitive resistor of with microbolometer sensor can be formed on the flexible polymer substrate material or on a dielectric layer on the flexible polymer substrate without a floating membrane. It can be advantageous to polish the flexible polymer surface to reduce the polymer surface roughness for the case that the ALD vanadium oxide material layer is deposited directly on the flexible polymer substrate. Alternately, a dielectric layer such as a thin ALD deposited aluminum oxide (Al2O3) can be deposited on the flexible polymer substrate prior to the deposition of an ALD vanadium oxide film on the surface of the Al2O3 layer. Advantages of a curved infrared focal plane imager include reduced number of lenses needed to reduce optical aberrations and increases to the field of view (FOV) of the imager.

### EXAMPLE 5

### Mixed Vanadium Oxide Material and Doped Vanadium Oxide Material

The temperature sensitive resistor material layer may comprise compounds of transition metal atoms that may include one or more of vanadium, lanthanum, manganese, titanium, or tungsten. In some embodiments, the transition metal atom is bonded with one or more oxygen atom(s). In some embodiments, the transition metal in the variable resistance material layer is bonded to one or more oxygen atoms to form a metal oxide.

In some embodiments, the temperature sensitive resistor material layer may comprise a vanadium oxide material layer with VOₓ bonded molecules content within the vanadium oxide material. In some embodiments, the variable resistance material layer may comprise multiple phases of transition metal compound. In some embodiments, the variable resistance material layer may comprise composite of VO₂ phase material, V₂O₅, phase material, V₂O₃ phase material, and, V₆O₁₃ phase material, and combinations thereof. In some embodiments, the variable resistance material layer comprises a composite for multiple vanadium oxide phases that is designated as VOₓ material.

The vanadium oxide film may comprise crystalline VO₂ material structures. The crystalline VO₂ material structure may comprise crystalline VO₂ grains, nanocrystals, or films. The vanadium oxide film with significant percentage of VO₂ crystalline material structures may have a reversible, temperature-dependent metal-to-insulator (MIT) phase transition temperature having a lower resistance values in the metal state in the insulator state. Vanadium oxide material with significant percentage of crystalline VO₂ bonded material structure may have a metal-to-insulator phase transition temperature of about 68° C. Below the phase transition temperature, the material is insulating and transparent, but above the phase transition temperature, the vanadium oxide film becomes metallic and reflective.

### EXAMPLE 6

In one embodiment, the one or more variable resistance material layer can be an atomic layer deposition (ALD) deposited vanadium oxide material layer that has VO₂ bonded molecules content within the vanadium oxide material and that comprise dopant atoms such as tungsten atoms have the advantage of modifying the phase transition temperature.

In the embodiments below, a vanadium oxide material layer may be a doped vanadium oxide material layer and may include dopant atoms or complexes such as tungsten or molybdenum or combinations therein.

### EXAMPLE 7

The metal-to-insulator phase transition temperature can be reduced by doping the variable resistance material layer(s) with dopant atoms that may include, but not be limited to, tungsten or molybdenum atoms.

The amorphous vanadium oxide material layer may be converted to a higher percentage of crystalline vanadium oxide structure by annealing. Laser annealing or electron beam annealing may be used to increase the percentage of crystalline vanadium oxide content in the vanadium oxide film. The thermal energy from the laser or electron bean annealing can be designed to deposit substantially within the vanadium oxide material layer and surrounding films without substantially heating the substrate. The laser or electron beam annealing may be used to optimize the temperature resistance properties of a VOₓ film to implement a microbolometer infrared focal plane array on a flexible glass or flexible polymer substrate.

The ALD vanadium oxide film can be deposited at low temperatures. The ALD vanadium oxide film can be deposited at as low as 115° C. The low deposition temperature capability enables the ALD vanadium oxide film to be deposited on polymer material. The low deposition temperature of the ALD vanadium oxide film deposition is advantageous to enable the deposition on a greater number of glass material type then would be possible for a higher deposition temperature deposition approach.

The ALD vanadium oxide film can be deposited on three-dimensional surfaces. The ability to deposit on three dimensional surface enable a larger effective thickness of the vanadium oxide material for increasing infrared electromagnetic absorption for infrared sensing applications or a larger effective thickness for increasing terahertz electromagnetic absorption for terahertz absorption.

The ALD vanadium oxide film offers advantages in a variety of applications including electrochemical applications, energy storage and conversion processes, thermoelectric devices, Mott transistors, and smart windows. Integrating solar cells that can efficiently harness and store solar energy into windows that require the material to be transparent has remained challenging.

A vanadium oxide material layer may be deposited on a membrane material layer from which a floating membrane will be formed for use for an infrared or terahertz imager. The membrane material layer may be a silicon nitride layer. The vanadium oxide layer will be used to form a temperature sensitive resistor. A vanadium oxide temperature sensitive resistor comprise a microbolometer sensor. The vanadium oxide material layer may be deposited by atomic layer deposition. In some embodiments, the vanadium oxide material layer can have a thickness in the range of about lnm to 10 nm. In some embodiments, the vanadium oxide material layer may have a thickness in the range of about lnm to 20 nm. In some embodiments, the vanadium oxide material layer may have a thickness in the range of about 1 nm to 50 nm. The vanadium oxide material layer may have a thickness in the range of about 1 nm to 100 nm. The advantage of a low thickness for the vanadium oxide film is that the response time of the detector is related to the thermal mass of the temperature sensor and a low thermal mass is advantageous for fast detector response speed. The thermal mass of the microbolometer detector is reduced by using a by reducing the thickness of vanadium oxide layer. In some embodiments, the vanadium oxide material may be deposited at a temperature of about 115° C. In some embodiments, the vanadium oxide material layer may be deposited at a temperature of about 150° C. In some embodiments, the vanadium oxide material layer may be deposited at a temperature of about 200° C. In some embodiments, the vanadium oxide material layer may be deposited at a temperature of about 300° C. In some embodiments, the membrane material layer may be deposited on a polymer with a transition temperature of about 100° C. The membrane material layer may be deposited on a polymer with a transition temperature of about 150° C. The membrane material layer may be deposited on a polymer with a transition temperature of about 200° C. The membrane material layer may be deposited on a polymer with a transition temperature of about 300° C. An advantage of polymer with low transition temperature is to facilitate the removal of the polymer layer to form a free standing membrane to reduce thermal conductance of the membrane to surrounding material layers. A capping layer may be deposited on the surface of the VOₓ layer to improve the stability of the VOₓ layer. The capping layer maybe deposited by atomic layer deposition. The capping layer maybe deposited within the same ALD system that is used to deposit the VOₓ layer. The capping layer material may include but be limited to Al₂O₃ or HfO₂. An infrared absorber material layer may be deposited on the surface of the vanadium oxide layer. A cavity to enhance the infrared absorption may be formed using material layers above and below the vanadium oxide layer. The cavity may be a 4/wavelength cavity. The cavity may be a resonant cavity. A cavity to enhance the terahertz absorption may be formed using material layers above and below the vanadium oxide layer.

Many modifications and variations of the present invention are possible in light of the above teachings. It is therefore to be understood that the claimed invention may be practiced otherwise than as specifically described. Any reference to claim elements in the singular, e.g., using the articles “a,” “an,” “the,” or “said” is not construed as limiting the element to the singular.

What we claim is:

1. A microbolometer comprising:
a substrate;
a membrane support;
a membrane on the membrane support;
an atomic layer deposition layer comprising vanadium oxide on the membrane;
an infrared absorber on the atomic layer deposition layer; and
a resistor electrode.

2. The microbolometer of claim 1 wherein the atomic layer deposition layer comprising vanadium oxide is unsaturated.

3. The microbolometer of claim 1 wherein the atomic layer deposition layer comprising vanadium oxide is one selected from the group consisting of unsaturated amorphous vanadium oxide material, unannealed unsaturated amorphous vanadium oxide material, unsaturated amorphous vanadium oxide material with greater than 90% VO₂ molecular content, annealed unsaturated vanadium oxide material, laser annealed unsaturated vanadium oxide material, and partially crystalline unsaturated amorphous oxide material.

4. The microbolometer of claim 2 wherein the resistor electrode is a temperature sensitive resistor electrode.

5. The microbolometer of claim 4 wherein the substrate is flexible.

6. The microbolometer of claim 5 wherein the substrate is flexible with a linear coefficient of thermal expansion less than 25 ppm/° C. at 300K.

7. The microbolometer of claim 6 wherein the atomic layer deposition layer comprising vanadium oxide is deposited on a three dimensional membrane structure.

8. The microbolometer of claim 6 wherein the atomic layer deposition layer comprising vanadium oxide is deposited at a temperature of less than 150° C.

9. The microbolometer of claim 6 wherein the atomic layer deposition layer comprising vanadium oxide is deposited at a temperature of less than 200° C.

10. The microbolometer of claim 6 further including a precursor for the vanadium oxide deposition.

11. The microbolometer of claim 7 wherein the atomic layer deposition layer comprising vanadium oxide is deposited at a temperature of 115° C.

12. A hemispherical curved infrared focal plane array comprising:
a flexible substrate with a linear thermal coefficient of expansion less than 25 ppm/° C. at 300K; and
an array of microbolometer sensors comprising an atomic layer deposition layer comprising vanadium oxide material layer deposited at a temperature less than 200° C. used to form a temperature sensitive resistor.

12. A hemispherical curved infrared focal plane array imager integrated circuit comprising:
a flexible substrate;
an array of microbolometer sensors comprising an atomic layer deposition layer comprising vanadium oxide used to form a temperature sensitive resistor formed over the flexible substrate;
one or more silicon CMOS die adhered or bonded to the flexible substrate; and
an electrical interconnect between the microbolometer array and the one or more silicon CMOS die.

13. The hemispherical curved infrared focal plane array imager integrated circuit of claim 12 wherein the electrical interconnect is formed using a microelectronic process.

14. The hemispherical curved infrared focal plane array imager integrated circuit of claim 12 wherein the electrical interconnect comprises a bump bond.

15. The hemispherical curved infrared focal plane array imager integrated circuit of claim 12 wherein the electrical interconnect is wire bonded or tape bonded.

16. The hemispherical curved infrared focal plane array imager integrated circuit of claim 12 wherein the vanadium oxide material layer used to form the temperature sensitive resistor is formed on a floating membrane layer.

17. The hemispherical curved infrared focal plane array imager integrated circuit of claim 12 wherein the vanadium oxide material layer used to form the temperature sensitive resistor is deposited on the flexible substrate or deposited on a dielectric layer deposited on the flexible substrate.

18. The hemispherical curved infrared focal plane array imager integrated circuit of claim 12 wherein the silicon CMOS die is a silion-on-insulator CMOS die and wherein the flexible substrate is stretchable.

19. A microbolometer comprising:
a substrate;
a membrane support;
a membrane;
an atomic layer deposition layer comprising vanadium oxide;
an infrared absorber; and
a resistor electrode;
wherein the VOₓ ALD film demonstrated 2.3%/K TCR and a conductivity of approximately 0.6/(ohm-cm).

20. A method of making a microbolometer comprising:
providing a substrate;
including a membrane support;
applying a membrane;
depositing an atomic layer deposition layer comprising vanadium oxide on the membrane;
depositing an infrared absorber; and
depositing a resistor electrode.
